(19) United States
(12) Patent Application Publication
(10) Pub. No.: US 2008/0185741 A1
(43) Pub. Date: Aug. 7, 2008

(54) Semiconductor device having dummy pattern

(75) Inventor: Junichi Sekine, Tokyo (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: ELPIDA MEMORY, INC., Tokyo (JP)

(21) Appl. No.: 12/068,306

(22) Filed: Feb. 5, 2008

(30) Foreign Application Priority Data
Feb. 6, 2007 (JP) 2007-027402

(51) Int. Cl. H01L 23/544

(52) U.S. Cl. 257/797; 257/E23.179

(57) ABSTRACT

A memory device having dummy pattern comprises: an alignment mark, provided at a predetermined position on a semiconductor substrate, for aligning position in manufacturing process based on an optical detection signal obtained by scanning in a first direction or in a second direction orthogonal to the first direction in a substrate plane; a real pattern formed in a wiring layer on the semiconductor substrate and used for circuit wiring; and a dummy pattern formed in the wiring layer and used in CMP method. The dummy pattern includes a plurality of basic patterns having a predetermined shape asymmetrical with respect to the first and second directions, and respective pattern portions crossing the basic patterns in the first and second directions in an area in which the dummy pattern is formed are not repeatedly arranged with a constant gap.

### BACKGROUND OF THE INVENTION

1. Field of the Invention

The present invention relates to a semiconductor device in which a dummy pattern for improving surface flatness in using CMP method is formed, and particularly relates to a semiconductor device in which a dummy pattern for avoiding recognition error with an alignment mark used for position alignment is formed.

2. Description of the Related Art

Generally, in manufacturing process of a semiconductor device, an interlayer insulation film is formed on an upper side of a wiring layer, and thereafter flattening of its surface is performed using CMP (Chemical Mechanical Polishing) method. At this point, since a pattern formed on the wiring layer is not distributed uniformly but maldistributed, the interlayer insulation film whose surface is polished by CMP method becomes thicker at an area having the pattern than at an area having no pattern, thereby deteriorating the flatness. A method for such a problem is known in which a regularly arranged dummy pattern is formed on the area having no pattern in the wiring layer so as to perform proper flattening using CMP method (e.g., see International Publication No. WO2004/082012 and Japanese Unexamined Patent Application Publication No. 2005-150389).

FIG. 6 shows a schematic plane view of a semiconductor device having a dummy pattern based on the above method. As shown in FIG. 6, a real pattern W forming circuit wiring and a dummy pattern D for the CMP method are arranged on a wiring layer of the semiconductor device. The dummy pattern D is formed so that a large number of square basic patterns are repeatedly arranged in X and Y directions with a constant gap. In this case, in order to improve the flatness of the CMP method, the real pattern W and the dummy pattern D are arranged so that a ratio of an area with any pattern and an area with no pattern is approximately equal to each other. By applying the CMP method to the interlayer insulation film on the wiring layer shown in FIG. 6, high flatness can be obtained.

Meanwhile, in order to align a position of a mask in manufacturing the semiconductor device, an alignment mark is provided at a predetermined position on a semiconductor substrate. By detecting the alignment mark optically, an accurate position of the mask can be determined based on a waveform of a detection signal. Explanation of the alignment mark will be made using FIGS. 7A and 7B. FIG. 7A shows an example of the alignment mark which is formed at a predetermined position on the semiconductor substrate and has a plurality of square patterns P. In this alignment mark, 15 square patterns P are regularly arranged, five of which are aligned in a lateral direction and three of which are aligned in a longitudinal direction, respectively with the same gap. A laser beam is irradiated to the alignment mark from the upper side and scanned in a scanning direction of FIG. 7A (indicated by a dotted arrow), for example, and its reflected light is detected. Here, the scanning direction for the alignment mark is assumed to be either the X direction or the Y direction of FIG. 6. The detection signal obtained from the reflected light of the laser beam has, for example, a signal waveform shown in FIG. 7B, in which five peaks appear at a constant period T corresponding to the existence of the pattern in the scanning direction.

However, since the dummy pattern D of FIG. 6 has a large number of square patterns aligned with a constant gap, it is similar to the pattern of the alignment mark in FIG. 7A. Therefore, if the laser beam is irradiated to an area including the dummy pattern D, there is a possibility that the dummy pattern D is erroneously recognized as the alignment mark. In this case, even if the period T is not accurately constant in the signal waveform of FIG. 7B, the possibility of the recognition error remains. Further, even if the recognition error when scanning in a certain direction is prevented by contriving the arrangement of the dummy pattern D, it is difficult to reliably prevent the recognition error when scanning along all straight lines assumed in the X and Y directions. In this manner, when the conventional dummy pattern D is employed for the purpose of improving the flatness of the CMP method in manufacturing the semiconductor device, it has been a problem that the positioning of the mask is not correctly performed due to the recognition error of the alignment mark.

### BRIEF SUMMARY OF THE INVENTION

An object of the present invention is to provide a semiconductor device with a simple structure in which a recognition error between a dummy pattern and an alignment mark is prevented when the dummy pattern used in CMP method is formed in the manufacturing process of the semiconductor device.

An aspect of the present invention is a semiconductor device having dummy pattern, comprising: an alignment mark, provided at a predetermined position on a semiconductor substrate, for aligning position in manufacturing process based on an optical detection signal obtained by scanning in a first direction or in a second direction orthogonal to the first direction in a substrate plane; a real pattern formed in a wiring layer on the semiconductor substrate and used for circuit wiring; and a dummy pattern formed in the wiring layer and used in CMP method, wherein said dummy pattern includes a plurality of basic patterns having a predetermined shape asymmetrical with respect to the first and second directions, and respective pattern portions crossing the basic patterns in the first and second directions in an area in which said dummy pattern is formed are not repeatedly arranged with a constant gap.

According to the semiconductor device of the present invention, the dummy pattern used for flattening by CMP method is formed in the wiring layer in addition to the real pattern, and the basic patterns included in the dummy pattern are arranged. Then, when scanning in the first or second direction in order to optically detect an alignment mark used for position alignment of a mask in manufacturing process, the arrangement in which pattern portions of the basic patterns do not appear with a constant gap in a scanning direction. Therefore, periodical peaks do not occur in a waveform of a detection signal, and it is reliably prevented that the dummy patter is erroneously recognized as the alignment mark.

In the present invention, pattern density of the area in which said dummy pattern is formed may be approximately the same as that of an area in which said real pattern is formed.

In the present invention, the plurality of basic patterns may include two kinds of basic patterns which are rotated by 180 degrees with respect to each other in a plane of the wiring layer.

In the present invention, each of the basic patterns may have a shape surrounded by straight lines in the first and second directions.

In the present invention, each of the basic patterns may have a shape obtained by removing portions of two opposite corners of a rectangle. In this case, each of the basic patterns may have a crank shape obtained by removing a rectangle from each of the two opposite corners, or may have a multiple crank shape obtained by removing a plurality of rectangles from each of the two opposite corners.

In the present invention, each of the basic patterns may have a shape surrounded by straight lines in directions different from the first and second directions in addition to the straight lines in the first and second directions.

In the present invention, said dummy pattern may include one or more modified patterns obtained by removing a portion of each of the basic patterns at a position adjacent to said real pattern or an area boundary. In this case, each of the basic patterns may be arranged adjacent to the other basic pattern or the modified pattern with a constant gap therebetween.

As described above, according to the present invention, the real pattern and the dummy pattern for the CMP are formed in the wiring layer of the semiconductor device which uses the alignment mark for aligning the position, and the dummy pattern is provided, which includes a plurality of the basic patterns each having a shape and an arrangement such that pattern portions thereof do not appear with a constant gap in the scanning direction assumed for the alignment mark. Accordingly, periodical peaks do not occur in the optical detection signal of the alignment mark, it is reliably prevented that the dummy patter is erroneously recognized as the alignment mark using a simple structure, and appropriate positioning of the semiconductor device can be performed in the manufacturing process while achieving the flattening of the CMP method.

### BRIEF DESCRIPTION OF THE DRAWINGS

The above and other objects and features of the invention will appear more fully hereinafter from a consideration of the following description taken in connection with the accompanying drawing wherein one example is illustrated by way of example, in which;

FIG. 1 is a schematic plane view of a first embodiment of a semiconductor device of the present invention;

FIG. 2 is an enlarged view of a basic pattern D(0) of FIG. 1;

FIG. 3 is a schematic plane view of a second embodiment of the semiconductor device of the present invention;

FIG. 4 is an enlarged view of a basic pattern D(10) of FIG. 3;

FIG. 5 is an enlarged view of a basic pattern D(20) which is a modification of the basic pattern D(0) of FIG. 2;

FIG. 6 is a schematic plane view of a semiconductor device having a conventional dummy pattern; and

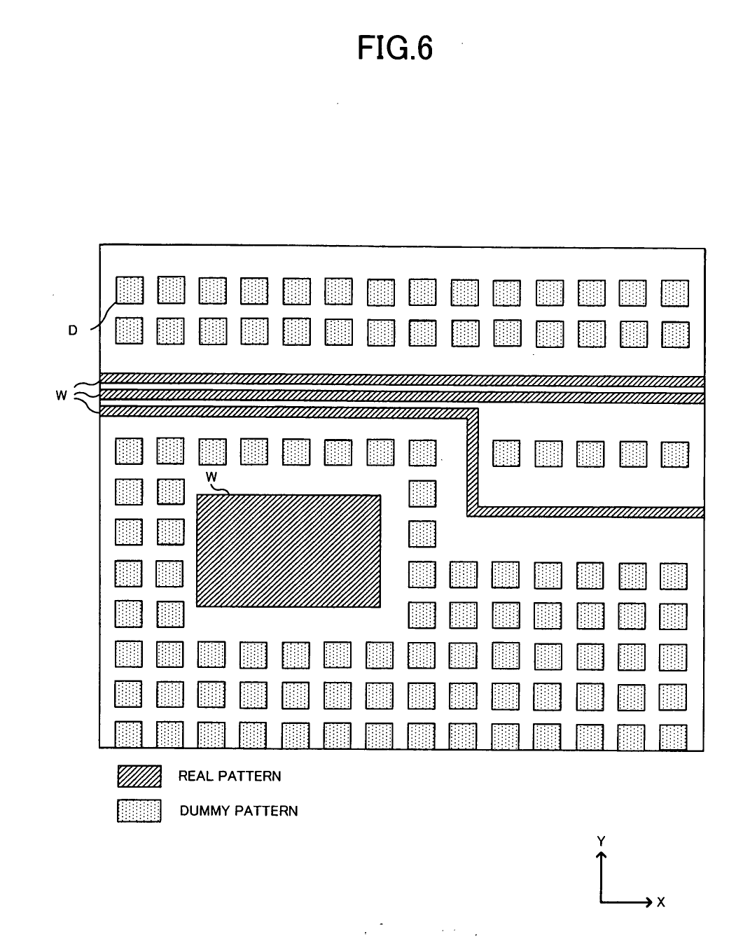

FIGS. 7A and 7B are diagrams showing an alignment mark provided on a semiconductor substrate and a waveform of a detection signal of the alignment mark.

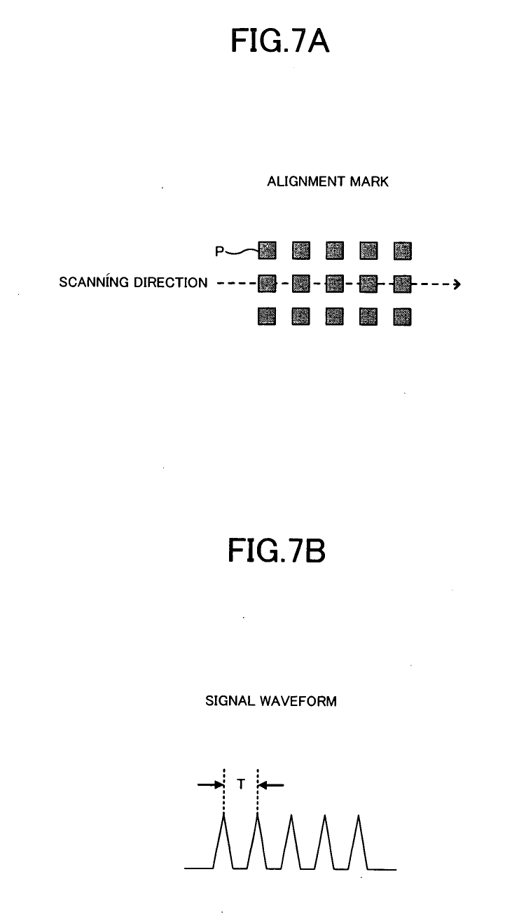

### DETAILED DESCRIPTION OF THE INVENTION

Hereinafter, preferred embodiments of the present invention will be described with reference to the drawings.

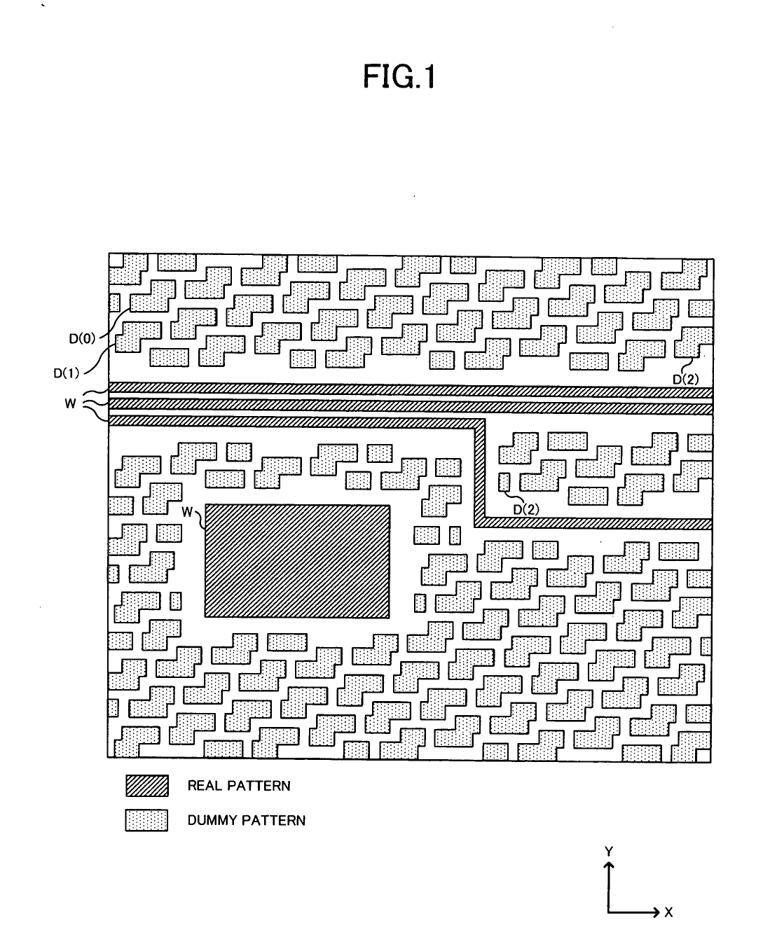

FIG. 1 is a schematic plane view of a first embodiment of a semiconductor device of the present invention. In the first embodiment, a wiring layer of the semiconductor device has an area in which a real pattern W for circuit wiring is formed and an area in which a dummy pattern D for CMP method is formed. In the lower side of FIG. 1, there are shown X direction (lateral direction) and Y direction (longitudinal direction) each as a reference. Three wiring lines and a square pattern are only shown in the real pattern W for the simplicity, but it has actually patterns of various shapes. The dummy pattern D includes basic patterns D(0) and D(1) of crank shapes and various modified patterns D(2) obtained by modifying the basic patterns D(0) and D(1).

As shown in FIG. 1, the basic patterns D(0) and D(1) have shapes asymmetrical with respect to X and Y directions, and both shapes are congruent with each other and rotated by 180 degrees with respect to each other in a plane. In most of the area of the dummy pattern D except the area of the real pattern W, either of two kinds of the basic patterns D(0) and D(1) is arranged. Meanwhile, each modified pattern D(2) has a partial shape of the basic patterns D(0) and D(1), and formed by removing a portion of each of the basic patterns D(0) and D(1) at a position adjacent to the real pattern W or an area boundary (outer edge portion) in order to obtain a predetermined gap therewith. Further, if elements including the basic patterns D(0) and D(1) and the modified patterns D(2) of the dummy pattern D are adjacent to each other, they are arranged with the predetermined gap.

Here, a ratio of an area with any pattern and an area with no pattern (pattern density) in the dummy pattern D is desired to be approximately equal to that in the real pattern D. If the pattern density is largely different between the areas of the dummy pattern D and the real pattern W, it has a bad influence on the flattening of the CMP method. Therefore, the pattern density may be calculated when the respective patterns in the area of the real pattern W are designed, and the size of the dummy pattern D and the gap between elements of the dummy pattern D may be set so as to be suitable for the pattern density. Here, if the size of the dummy pattern D and the gap between the elements of the dummy pattern D are set too large, a partial area with any pattern or with no pattern becomes large, which is undesirable in terms of the CMP method. Therefore, it is required to arrange the dummy pattern D with the size and the gap which are small to some extent.

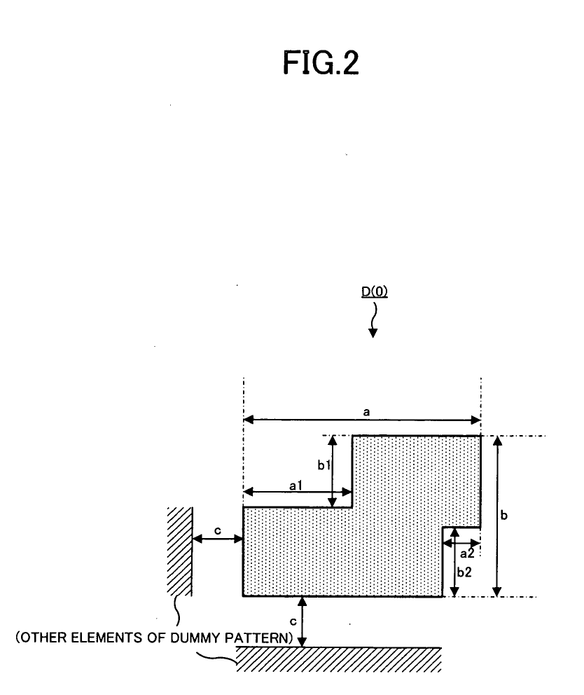

FIG. 2 shows an enlarged view of the basic pattern D(0) of FIG. 1. The basic pattern D(0) as shown in FIG. 2 has a shape (crank shape) obtained by removing a rectangle of a1×b1 (the length of X direction is a1 and the length of Y direction is b1; hereinafter denoted in the same way) and a rectangle of a2×b2 from a rectangle of a×b at two opposite corners. This example satisfies a relation of a>a1+a2, b>b1+b2, a1>a2 and b1>b2. A symmetrical arrangement to FIG. 2 may be assumed for the other basic pattern D(1).

The basic pattern D(0) and an adjacent element of the dummy pattern D are spaced with a gap c according to a layout rule of the semiconductor device. In FIG. 2, two elements of the dummy pattern D adjacent to two sides of the basic pattern D(0) are shown, however it is required that all sides (not shown) of the basic pattern D(0) and adjacent elements of the dummy pattern D need to be spaced with the above gap c. Meanwhile, if the basic pattern D(0) is adjacent to the real pattern W, it is required that they need to be spaced with a predetermined gap larger than the gap c (see FIG. 1). This layout rule between the element of dummy pattern D and the adjacent pattern is common for the other basic pattern D(1) and the modified pattern D(2) in addition to the basic pattern D(1).

Returning to FIG. 1, a case in which a scanning direction of a laser beam for an alignment mark is set for the dummy pattern D having the above shape and arrangement in X or Y direction through an arbitrary position will be considered. Here, when attention is paid to a plurality of the basic patterns D(0) or a plurality of the basic patterns D(1) which are adjacent in the X direction, positions thereof in the Y direction are gradually shifted one another. When scanning in the X direction, the light crosses any pattern portion having a length a-a1 (left side), a length a (center), or a length a-a2 (right side) in FIG. 2, and does not successively cross a pattern portion of the same position. Thus, the pattern with the constant gap does not appear repeatedly, and it can be avoided that the waveform of the detection signal has a constant period.

Meanwhile, when attention is paid to a plurality of the basic patterns D(0) or a plurality of the basic patterns D(1) which are adjacent in the Y direction, positions thereof in the X direction are gradually shifted one another. When scanning in the Y-direction, the light crosses any pattern portion of a length b-b1 (lower side), a length b(center), or a length b-b2 (upper side) in FIG. 2, and does not successively cross a pattern portion of the same position. Thus, the pattern with the constant gap does not appear repeatedly, and it can be avoided that the waveform of the detection signal has a constant period. As described above, there is no place where the existence and absence of each element of the dummy pattern D appear with the constant gap in the scanning direction in each of the X and Y directions, and the recognition error of the alignment mark can be reliably prevented.

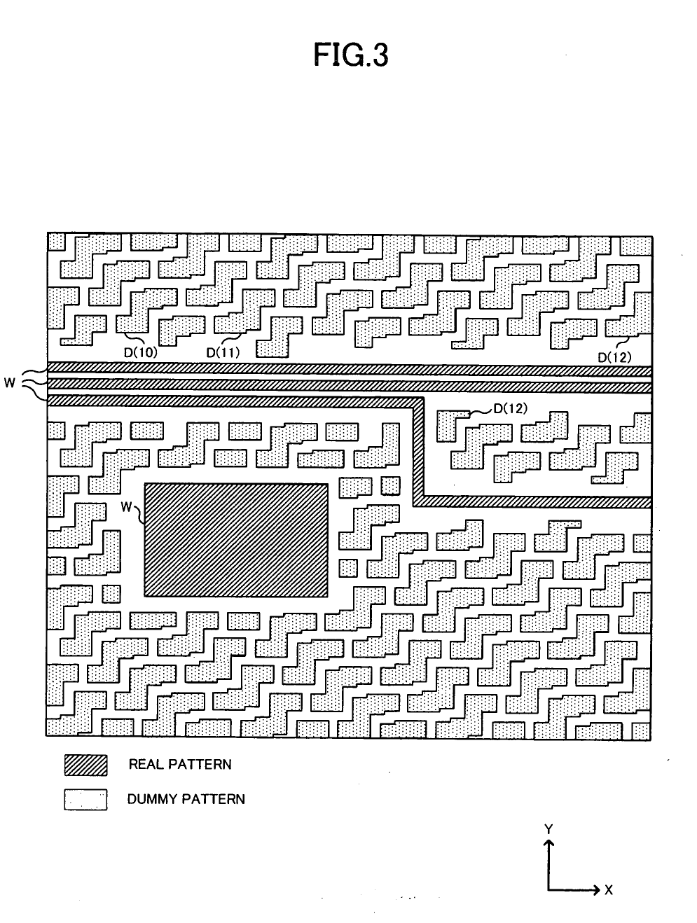

Next, FIG. 3 is a schematic plane view of a second embodiment of a semiconductor device of the present invention. In the second embodiment, there are an area of the real pattern W and an area of the dummy pattern D in the wiring layer of the semiconductor device, similarly as in the first embodiment, however the shape of each element of the dummy pattern D is different form the first embodiment. Note that the shape of the real pattern W of FIG. 3 is the same as the shape of the real pattern W of FIG. 1. The dummy pattern D of FIG. 3 includes basic patterns D(10) and D(11) of more complicated crank shapes (hereinafter referred as “double crank shape”) than FIG. 1 and various modified patterns D(12) obtained by modifying the basic patterns D(10) and D(11).

As shown in FIG. 3, the basic pattern D(10) and the basic pattern D(11) have asymmetrical shapes with respect to the X and Y directions, and both shapes are congruent with each other and rotated by 180 degrees with respect to each other in a plane. In most of the area of the dummy pattern D except the area of the real pattern W, either of two kinds of the basic patterns D(10) and D(11) is arranged. Meanwhile, each modified pattern D(12) has a partial shape of the basic patterns D(10) and D(11), and formed by removing a portion of each of the basic patterns D(10) and D(11) at a position adjacent to the real pattern W or an area boundary (outer edge portion) in order to obtain a predetermined gap therewith. Further, if elements including the basic patterns D(10) and D(11) and the modified patterns D(12) of the dummy pattern D are adjacent to each other, they are arranged with the predetermined gap.

In addition, the pattern density of the area of the dummy pattern D is desired to be approximately equal to the pattern density of the area of the real pattern W, as in the first embodiment. Further, the size of the dummy pattern D and the gap between elements of the dummy pattern D need to be set small to some extent, as in the first embodiment.

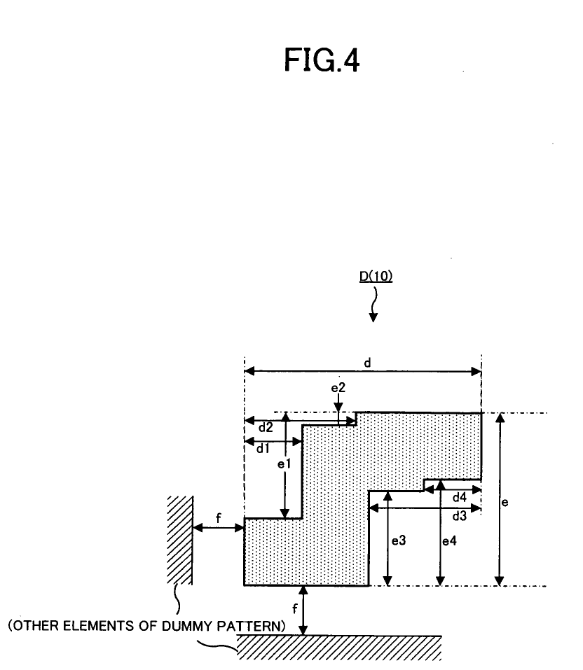

FIG. 4 shows an enlarged view of the basic pattern D(10) of FIG. 3. The basic pattern D(10) as shown in FIG. 4 has a shape (double crank shape) obtained by removing a rectangle of d1×e1 (the length of X direction is d1 and the length of Y direction is e1; hereinafter denoted in the same way) and a rectangle of d2×e2 at one of two opposite corners and by removing a rectangle of d3×e3 and a rectangle of d4×e4 at the other thereof, respectively from a rectangle of d×e. This example satisfies a relation of d>d2+d3, e<e1+e4, d2>d1, d3>d4, e1>e2 and e4>e3. A symmetrical arrangement to FIG. 4 may be assumed for the other basic pattern D(11).

The basic pattern D(10) and an adjacent element of the dummy pattern D are spaced with a gap f according to a layout rule of the semiconductor device. In FIG. 4, two elements of the dummy pattern D adjacent to two sides of the basic pattern D(10) are shown, however it is required that all sides (not shown) of the basic pattern D(10) and adjacent elements of the dummy pattern D need to be spaced with the above gap f. Meanwhile, if the basic pattern D(10) is adjacent to the real pattern W, it is required that they need to be spaced with a predetermined gap larger than the gap f (see FIG. 3). This layout rule between the element of dummy pattern D and the adjacent pattern is common for the other basic pattern D(11) and the modified pattern D(12) in addition to the basic pattern D(11).

Returning to FIG. 3, a case in which a scanning direction of the laser beam for the alignment mark is set for the dummy pattern D having the above shape and arrangement in X or Y direction through an arbitrary position will be considered. Here, when attention is paid to a plurality of the basic patterns D(10) or a plurality of the basic patterns D(11) which are adjacent in the X direction, positions thereof in the Y direction are gradually shifted one another. When scanning in the X direction, the light crosses one of pattern portions having five kinds of lengths (d-d2, d-d1, d-d1-d4, d-d1-d3 and d-d3 from the top of FIG. 4) depending on the positions, and does not successively cross a pattern portion of the same position. Thus, the pattern with the constant gap does not appear repeatedly, and it can be avoided that the waveform of the detection signal has a constant period.

Meanwhile, when attention is paid to a plurality of the basic patterns D(10) or a plurality of the basic patterns D(11) which are adjacent in the Y direction, positions thereof in the X direction are gradually shifted one another. When scanning in the Y direction, the light crosses one of pattern portions having five kinds of lengths (e-e1, e-e2, e, e-e3 and e-e4 from the left of FIG. 4) depending on the positions, and does not successively cross a pattern portion of the same position. Thus, the pattern with the constant gap does not appear repeatedly, and it can be avoided that the waveform of the detection signal has a constant period. As described above, there is no place where the existence and absence of each element of the dummy pattern D appear with the constant gap in the scanning direction in each of the X and Y directions, and the recognition error of the alignment mark can be reliably prevented.

In the forgoing, the dummy pattern D having the crank shape is formed in the first embodiment, and the dummy pattern D having the double crank shape is formed in the second embodiment. However, the present invention is not limited to the embodiments, and a dummy pattern D may be formed which has a multiple crank shape obtained by removing a plurality of rectangles from each of two opposite corners.

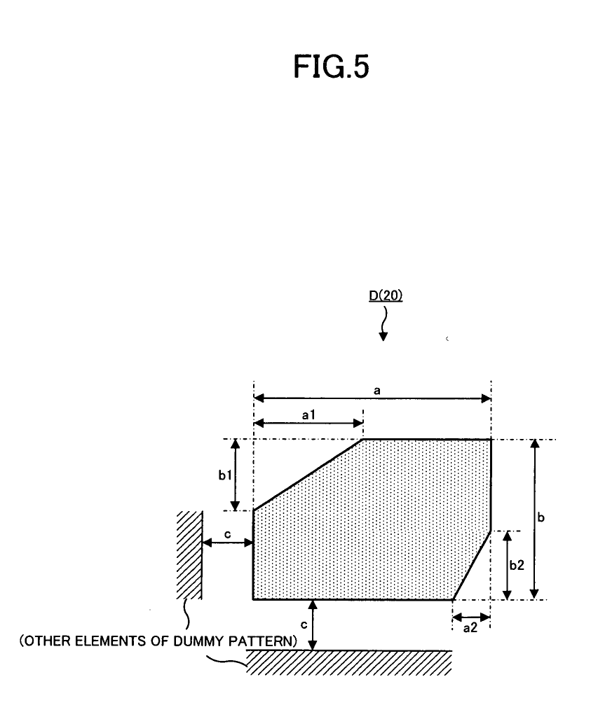

Further, in the first and second embodiments, the dummy pattern D having a shape surrounded by straight lines in the X and Y directions has been described, however the dummy pattern D may partially include straight lines in directions different from the X and Y directions. FIG. 5 shows an enlarged view of a basic pattern D(20) which is a modification of the basic pattern D(0) shown in FIG. 2, as an example of an element of the dummy pattern D having such a shape. The basic pattern D(20) as shown in FIG. 5 has a shape obtained by removing a triangle from each of the two opposite corners of FIG. 2. The basic pattern D(20) includes two straight lines corresponding to diagonal lines of a rectangle of a1×b1 and a rectangle of a2×b2 (respective sizes are shown in FIG. 2).

In a case where the basic patterns D(0) of FIG. 1 are replaced with basic patterns D(20) of FIG. 5 to arrange the dummy pattern D, when scanning in the X and Y directions, the pattern with the constant gap does not appear repeatedly, thereby achieving the same effect. In addition, the element of the dummy pattern D in the modification of FIG. 5 includes straight lines in diagonal directions, however the element of the dummy pattern D of the first and second embodiments includes only straight lines in the X and Y directions, so that the size of the mask data for the wiring layer can be reduced.

As described above, by employing the dummy pattern D of the embodiments, an arrangement is achieved in which a large number of the basic patterns are irregularly arranged in the X and Y directions and pattern portions crossing the dummy pattern D do not appear with the constant gap. Thus, when scanning the alignment mark in the X or Y direction in manufacturing process, it is avoided that peaks of a constant period occur in the waveform of the detection signal, and it is possible to prevent that the dummy pattern D is erroneously recognized as the alignment mark. Therefore, the semiconductor device can be manufactured without hindering the position alignment of the mask.

The present invention is not limited to the above-described embodiments and can be variously modified without deviating from the scope of the invention. For example, the shape of the basic pattern in the dummy pattern D is not limited to shapes shown in FIGS. 1 to 5, and various shapes capable of achieving the same effect can be applied. Further, in a case where the dummy pattern D partially includes pattern portions of the constant gap, if this gap is largely different from the gap of the pattern of the alignment mark, the recognition error of the alignment mark can be prevented.

The present invention is not limited to the above described embodiments, and various variations and modifications may be possible without departing from the scope of the present invention.

This application is based on the Japanese Patent application No. 2007-027402 filed on Feb. 6, 2007, entire content of which is expressly incorporated by reference herein.

What is claimed is:

1. A semiconductor memory device having dummy pattern, comprising:
an alignment mark, provided at a predetermined position on a semiconductor substrate, for aligning position in manufacturing process based on an optical detection signal obtained by scanning in a first direction or in a second direction orthogonal to the first direction in a substrate plane;
a real pattern formed in a wiring layer on the semiconductor substrate and used for circuit wiring; and
a dummy pattern formed in the wiring layer and used in CMP method,
wherein said dummy pattern includes a plurality of basic patterns having a predetermined shape asymmetrical with respect to the first and second directions, and respective pattern portions crossing the basic patterns in the first and second directions in an area in which said dummy pattern is formed are not repeatedly arranged with a constant gap.

2. The semiconductor memory device having dummy pattern according to claim 1, wherein pattern density of the area in which said dummy pattern is formed is approximately the same as that of an area in which said real pattern is formed.

3. The semiconductor memory device having dummy pattern according to claim 1, wherein the plurality of basic patterns includes two kinds of basic patterns which are rotated by 180 degrees with respect to each other in a plane of the wiring layer.

4. The semiconductor memory device having dummy pattern according to claim 3, wherein each of the basic patterns has a shape surrounded by straight lines in the first and second directions.

5. The semiconductor memory device having dummy pattern according to claim 4, wherein each of the basic patterns has a shape obtained by removing portions of two opposite corners of a rectangle.

6. The semiconductor memory device having dummy pattern according to claim 5, wherein each of the basic patterns has a crank shape obtained by removing a rectangle from each of the two opposite corners.

7. The semiconductor memory device having dummy pattern according to claim 5, wherein each of the basic patterns has a multiple crank shape obtained by removing a plurality of rectangles from each of the two opposite corners.

8. The semiconductor memory device having dummy pattern according to claim 3, wherein each of the basic patterns has a shape surrounded by straight lines in directions different from the first and second directions in addition to the straight lines in the first and second directions.

9. The semiconductor memory device having dummy pattern according to claim 1, wherein said dummy pattern includes one or more modified patterns obtained by removing a portion of each of the basic patterns at a position adjacent to said real pattern or an area boundary.

10. The semiconductor memory device having dummy pattern according to claim 9, wherein each of the basic patterns is arranged adjacent to the other basic pattern or the modified pattern with a constant gap therebetween.
